(19) United States
(12) Patent Application Publication
(10) Pub. No.: US 2026/0128089 A1
(43) Pub. Date: May 7, 2026

(54) STORAGE CIRCUITRY FOR READ AND WRITE OPERATIONS

(71) Applicant: Arm Limited, Cambridge (GB)

(72) Inventors: Kedhar MALLA, Bangalore (IN); Navin AGARWAL, Bangalore (IN); Rajiv Kumar SISODIA, Bangalore (IN); Sunil KUMAR KROVI, Bangalore (IN); Abhishek Kumar SINGH, Bangalore (IN); Sumant KUMAR THAPLIYAL, Bangalore (IN)

(21) Appl. No.: 18/939,932

(22) Filed: Nov. 7, 2024

(51) Int. Cl. G11C 11/419; H03K 19/20

(52) U.S. Cl. CPC G11C 11/419; H03K 19/20

(57) ABSTRACT

Storage circuitry devices, systems, and methods including a bitcell array having a plurality of bitcells, each bitcell accessible via a bitline and wordline, where the bitcell array is provided at a first layer of the storage circuitry; a redundant array associated with the bitcell array, the redundant array having a plurality of redundant bitcells, each redundant bitcell accessed via a redundant bitline and redundant wordline, where the bitcell array is provided at a second layer of the storage circuitry.

### TECHNICAL FIELD

The present techniques relate to a storage system (or device) and circuitry (or circuits) therefor and particularly, but not exclusively, to row redundancy architectures for use within such systems and circuitry.

### BACKGROUND

Conventional storage systems, such as static random access memory (SRAM) systems provide redundant rows within arrays of storage cells (bitcells). In this way, should a defect arise which renders a row inoperative, then one of the redundant rows may be functionally substituted for the row in which the defect has arisen.

Conventional row redundancy mechanisms represent an additional overhead in terms of circuit area, power consumption, complexity, and timing which has to be carried by every integrated circuit irrespective of whether or not the redundancy mechanisms for that integrated circuit are needed within the particular instance.

### SUMMARY

The present techniques relate to improving row redundancy mechanisms.

According to a first aspect of present techniques there is provided storage circuitry comprising: a bitcell array having a plurality of bitcells, each bitcell accessible via at least one bitline and at least one wordline, where the bitcell array is provided at a first layer of the storage circuitry; a redundant array associated with the bitcell array, the redundant array having a plurality of redundant bitcells, each redundant bitcell accessed via at least one redundant bitline and at least one redundant wordline, where the bitcell array is provided at a second layer of the storage circuitry.

According to a further aspect of present techniques, there is provided a method of controlling a read or write operation at storage circuitry comprising a bitcell array having a plurality of bitcells, each bitcell accessible via a bitline and wordline, where the bitcell array is provided at a first layer of the storage circuitry and a redundant array associated with the bitcell array, the redundant array having a plurality of redundant bitcells, each redundant bitcell accessed via a redundant bitline and redundant wordline, where the bitcell array is provided at a second layer of the storage circuitry.

According to a further aspect of present techniques, there is provided a non-transitory computer-readable medium to store computer-readable code for fabrication of any circuitry described herein.

### BRIEF DESCRIPTION OF THE DRAWINGS

Various embodiments using the present techniques will now be described by way of example only and with reference to the accompanying drawings in which:

FIG. 1a shows a block level diagram of conventional storage circuitry;

FIG. 1b shows a portion of the conventional storage circuitry of FIG. 1 in greater detail;

FIG. 2 shows a block level diagram of a portion of storage circuitry in accordance with the present techniques;

FIG. 3a shows a portion of the storage circuitry of FIG. 2 in more detail in accordance with an embodiment of the present techniques.

FIG. 3b shows a portion of the storage circuitry of FIG. 3a in more detail in accordance with an embodiment of the present techniques;

FIG. 4 shows a portion of the storage circuitry of FIG. 2 in accordance with a further embodiment of the present techniques;

FIG. 5 shows an example embodiment of redundant row address circuitry of the storage circuitry of FIG. 2;

FIG. 6a shows a waveform diagram for a read operation performed at the storage circuitry of FIG. 2;

FIG. 6b shows a waveform diagram for a write operation performed at the storage circuitry of FIG. 2;

FIG. 7a shows an example of write signal generation logic in accordance with the present techniques;

FIG. 7b shows an example of fault write signal generation logic in accordance with the present techniques FIG. 7c shows an example of read signal generation logic in accordance with the present techniques;

FIG. 7d shows an example of fault read signal generation logic in accordance with the present techniques; and

FIG. 8 illustrates a process flow diagram for a manufacturing operation for fabricating storage circuitry in accordance with the present techniques.

Details of methods, apparatuses, and processors according to examples will become apparent from the following description, with reference to the Figures. In this description, for the purpose of explanation, numerous specific details of certain examples are set forth. Reference in the specification to ‘an example’ or similar language means that a particular feature, structure, or characteristic described in connection with the example is included in at least that one example, but not necessarily in other examples. It should further be noted that certain examples are described schematically with certain features omitted and/or necessarily simplified for ease of explanation and understanding of the concepts underlying the examples.

### DETAILED DESCRIPTION

Integrated circuits (ICs) include structures formed of layers where each layer may comprise polysilicon gate material in various regions and sequences of spaced apart layers of metal lines. The polysilicon gate material is deposited in fingers and is typically used to form the gate material within transistors. The metal lines (e.g. bitlines/wordlines) are used to carry signals to read and write data, and to connect to the other components within the IC. Such an IC may be used for storage (memory) circuitry, such as static random access memory.

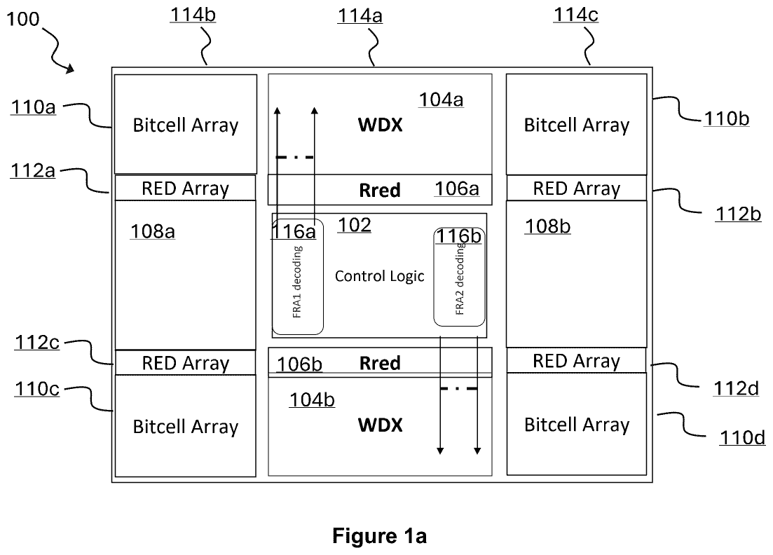

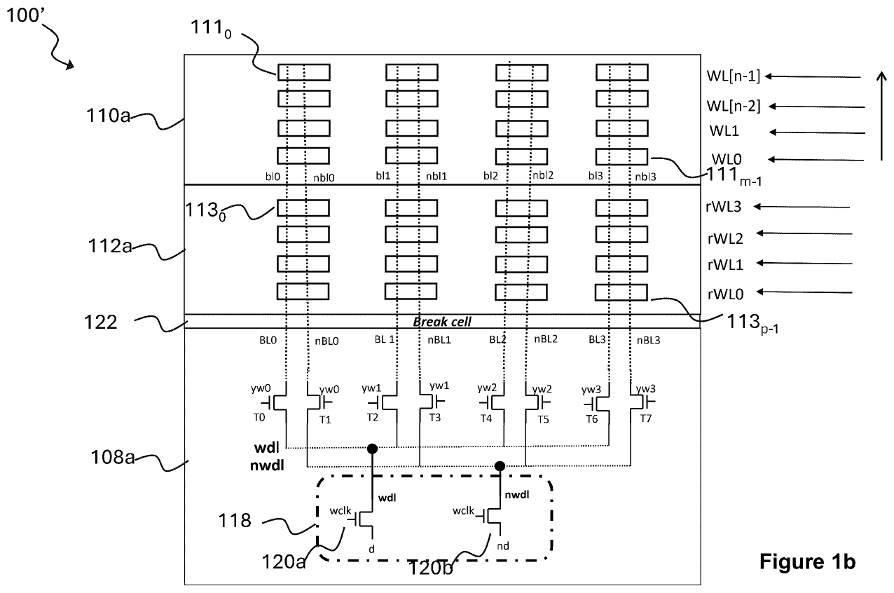

FIG. 1a shows a block level diagram of conventional storage circuitry 100 and FIG. 1b shows a portion 100′ of the conventional storage circuitry 100 in more detail.

The storage circuitry 100 includes various components (or elements or modules) including, control logic 102, wordline selection (WDX) circuitry 104a/b, redundant row wordline selection (Rred) circuitry 106a/b, peripheral or column selection (Cmux) circuitry 108a/108b, write driver (WR) circuitry and read or sense amplifier circuity (not shown in FIG. 1a), a plurality of storage cells or bitcells (hereafter “bitcells”) arranged in one or more arrays 110a-d (hereafter “bitcell array”).

Each bitcell of a bitcell array 110a-d may be configured to store at least one data bit value (e.g., a data value related to a logical ‘0’ or ‘1’). In various instances, each array of the bitcell arrays 110a-d may include any number of bitcells that are arranged in various applicable configurations of columns (Ncolumns) and rows (Nrows).

To provide row redundancy in the storage circuitry 100, each bitcell array 110a-d has an associated array of redundant bitcells (hereafter “redundant array”), where each redundant array 112a-d comprises a plurality of redundant bitcells arranged in a similar configuration as the plurality of bitcells of the associated bitcell array 110a-d (i.e. same number of columns and where the number of rows is reduced dependent on the number of redundant bitcells in a redundant array). When providing row redundancy, the redundant arrays are manufactured on the same layer (poly or metal layer) of the storage circuitry 100.

Each redundant bitcell of a redundant array 112a-d may be configured to store at least one data bit value (e.g., a data value related to a logical ‘0’ or ‘1’). In various instances, each redundant array 112 may include any number of redundant bitcells that are arranged in a substantially similar configuration as the bitcells of an associated bitcell array.

In FIG. 1a, the storage circuitry 100 is embodied as a MUX 4: 256×4 core array with four bitcell arrays 110a-d, each bitcell array having 256 rows of addressable bitcells arranged in four columns and each bitcell array 100a-d having an associated redundant array 112a-d, each redundant array 112a-d having 4 rows of addressable redundant bitcells arranged in four columns.

The number of redundant arrays and the number of redundant bitcells may be provided based on requirements of a foundry manufacturing the storage circuitry. For example, the number of redundant bitcells may be increased when the number of faulty bitcells in the bitcell arrays is expected to be relatively high (e.g. due to problems such as material quality or manufacturing issues at the foundry). As will be appreciated, adding row redundancy in the conventional storage circuitry 100 incurs a timing and area penalty, where the address set up time is increased and the area of the silicon is also impacted as a result of the additional circuitry required to address/access the redundant bitcells.

Each individual bitcell in a bitcell array 110 may be accessed by triggering (asserting) a corresponding wordline (WL) and corresponding bitlines (BL/NBL).

In FIG. 1a, the storage circuitry 100 is depicted as having a butterfly architecture having the control logic 102, WDX circuitry 104a/b for controlling wordlines (wl) signals on wordlines (WL) and Rred circuitry 106a/106b for controlling redundant wordlines signals (rwl) on redundant wordlines (rWL), in a middle section.

Bitcell arrays 110a & 110c and associated redundant arrays 112a & 112c are arranged at a first side 114b of the butterfly architecture and bitcell arrays 110b & 110d and associated redundant arrays 112b & 112d are arranged at a second side 114c.

Similarly, column selection circuitry 108a/108b for providing an appropriate bitline (bl/nbl) signals to the columns of bitcells and redundant bitcells via bitlines (BL/NBL) is provided at the respective sides 114b/c.

A memory controller(s) at a processor (not shown in FIG. 1a/1b) may access the storage circuitry 100 via a bus or interconnect. In some embodiments the storage circuitry may be integrated with the processor, where the storage circuitry may be part of a storage hierarchy, such as a cache (e.g. L1, L2 cache). In embodiments the storage circuitry may be static random access memory (SRAM).

As depicted in FIG. 1a, Rred circuitry 106b and faulty row address (FRA) circuitry 116a/b are provided to generate the signals to access redundant arrays 112a-d, where two Rred circuits 106a/b and two FRA circuits 116a/116b are depicted in FIG. 1a, but in other implementations Rred circuitry and/or FRA comparator logic circuits may be provided for each redundant array 112a-d. The FRA comparator circuits 116a/116b may comprise various logic (e.g. comparator logic).

The FRA circuitry 116a/b which comprises decoding logic and comparator logic to check/detect the FRA and trigger a redundant WL (rWL) to select a particular redundant row is provided for the various redundant rows. The rWL will be triggered based on matching signals through row-address.

In the present illustrative example of the conventional storage circuit, each redundant array 112a-d comprises four rows of redundant bitcells to support an associated bitcell array of 256 rows of bitcells. Thus, a minimum of 8 bits is required to detect a faulty row address in the bitcell array from 0 to 255.

As an illustrative example, the comparator logic is standard cell based and given the requirement to detect an address from 0 to 255, the size will be limited by the requirement to have 16 signal (metal) tracks, so the comparator logic will be at least 4 standard cells (SC) high. In FIG. 1a, the two FRA circuits provided for row redundancy requires an area overhead of at least 8 SC. Thus, the FRA circuitry required to provide the row redundancy incurs an additional area overhead compared to a storage circuit that does not include row redundancy.

FIG. 1b shows a portion 100′ of the storage circuitry 100 of FIG. 1a. In particular, FIG. 1b depicts bitcell array 110a comprising “m” bitcells 111₀ to 111ₘ₋₁ (where in the present example m=1024) arranged in four columns and 256 rows (four of which are depicted in FIG. 1b). FIG. 1b also depicts associated redundant array 112a comprising “p” redundant bitcells 113₀ to 113ₚ₋₁ (where in the present example p=16) arranged in four columns and four rows.

FIG. 1b also depicts column selection circuitry 108a, which in the present example comprises column write circuitry, comprising column multiplexer write devices or column write devices (CW) designated for write operations that are arranged to operate as a write multiplexer and coupled to corresponding bitlines (BL & nBL) along which bitlines signals (bl/nbl) will propagate to select (or enable) bitcells and redundant bitcells in a particular column to write data thereto.

In FIG. 1b, column multiplexer write device (CW) device may comprise pass-gates comprising pairs of NMOS transistors(e.g. T0, T1, T2, T3, T4, T5, T6 & T7) that are arranged in parallel.

The transistors T0, T2, T4 & T6 are coupled between corresponding bitlines (e.g. BL0, BL1, BL2, BL3) and first write data line (WDL) to receive a write data line (wdl) signal from write driver circuitry 118.

The transistors T1, T3, T5 & T7 are coupled between corresponding bitlines (e.g. nBL0, nBL1, nBL2, nBL3) and second write data line (nWDL) to receive a complementary write data line (nwdl) signal from write driver circuitry 118.

The write driver (WR) circuitry 118 may be part of the column selection circuitry 108, and may comprise at least one write driver 120a/b (two of which are depicted in FIG. 1b).

A first write driver 120a receives a write clock signal (wclk) and data signal (d) as inputs and provides a write data line (wdl) signal as the output to the column mux devices T0, T2, T4, T6. A second write driver 120b receives a write clock signal (wclk) and complementary data signal (nd) as inputs and provides a complementary write data line (nwdl) signal as the output to the column mux devices T1, T3, T5, T7.

Column multiplexer write select signals (yw & nyw) which each comprise a transition signal are provided to control CW devices to, for example, couple/decouple (or connect/disconnect) a selected bitline to/from the write drivers 120a/b by controlling a respective CW device during a write operation.

Although not shown in FIG. 1b, the column selection circuitry 108 also includes one or more column multiplexer read devices or column read (CR) devices designated for read operations that are arranged to operate as a read multiplexer and are coupled to corresponding bitlines (BL & nBL) along which bitlines signals (bl/nbl) will propagate to select (or enable) bitcells and redundant bitcells in a particular column to enable sense amplifier circuitry to read or sense data there from a particular bitcell in that column, when activated responsive to a wordline (WL) signal or redundant wordline signal (rWL).

Each CR device comprises pass-gates comprising pairs of PMOS transistors that are arranged in parallel. The pairs of PMOS transistors are coupled between the corresponding bitlines (BL0, BL1, BL2, BL3 and nBL0, nBL1, nBL2, nBL3) and sensed data lines (SD & NSD) which are coupled to the output of sense amplifier (SA) circuitry.

Column multiplexer read select signals (yr & nyr) which each comprise a transition signal are provided to control the CR devices to, for example, couple/decouple (or connect/disconnect) a selected bitline to/from the SA circuitry by controlling a respective CR device during a write operation.

As will be understood, the control logic 102 may include clock generation circuitry (not shown) that may receive a clock signal (clk) (e.g. an external clock signal) and, responsive to the external clock signal may provide an internal clock signal (such as a global timing pulse (gtp) signal) to the various circuitry to initiate a particular read or write operation as appropriate.

Furthermore, as will be understood, when fabricating storage circuit 100′ such as that depicted in FIG. 1b the bitcell array 110a, redundant array 112a may be fabricated to meet first design rules checks (DRC) constraints (e.g. minimum feature size, spacing requirements, geometric constraints etc.) whereas the column selection circuitry 108a may be required to meet different DRC constraints. Thus, to merge the bitcell array 110a and redundant array 112a circuitry with the column selection circuitry 108a, a break cell 122 may be provided as a buffer between the different circuitry, where the break cell length may be dependent on the technology used.

The present techniques relate to improving conventional row redundancy mechanisms by addressing inter alia the timing and area penalties that are evident in conventional storage circuitry.

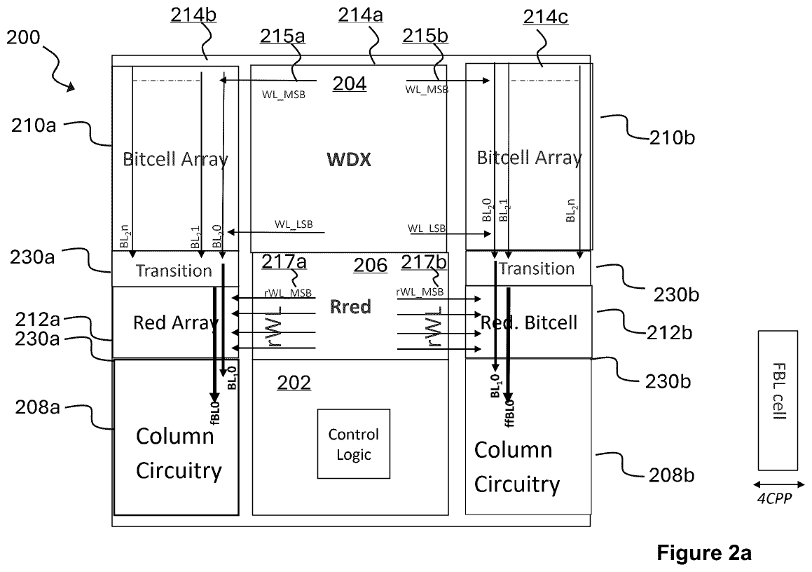

FIG. 2 shows a block level diagram of a portion of storage circuitry 200 in accordance with the present techniques.

The storage circuitry 200 includes control logic 202, WDX circuitry 204a, redundant row wordline selection (Rred) circuitry 206, Cmux circuitry 208a/208b, bitcell arrays 210a/b, and an associated redundant array 212a/b for each of the bitcell arrays 210a/b.

Similar to the conventional storage circuitry depicted in FIG. 1a, the storage circuitry 200 is depicted as having a butterfly architecture, and where the storage circuitry 200 may be static random access memory (SRAM).

Each bitcell array 210a/b comprises 256 rows of bitcells, where each row comprises four bitcells. Furthermore, each redundant array 212a/b comprises 16 bitcells arranged in four rows, where each redundant row comprises four redundant bitcells.

In contrast to the conventional storage circuitry (e.g. as depicted in FIG. 1a), where the bitcell arrays and associated redundant arrays are arranged in the same metal or poly layer, in accordance with the present techniques the bitcell arrays 210a/b and associated redundant arrays 212a/b are provided [fabricated] in different layers (e.g. polysilicon or metal layers) of the storage circuit 200. Thus, the bitcells of the bitcell arrays 210a/b and the redundant bitcells of the associated redundant arrays 212a/b are provided in different layers to one another.

To accommodate the bitcell arrays 210a/b and associated redundant arrays 212a/b being in different layers, a transition region 230a/b is provided to electrically couple different portions of bitlines or redundant bitline portions as will be described in more detail below. In the present illustrative example the transition region 230a/b, comprises a flexible or floating bitline (FBL) cell provided between the bitcell arrays 210a/b and associated redundant arrays 212a/b.

In the present illustrative example, each bitcell array 210 comprises 256 rows of bitcells. Therefore, the layer (polysilicon or metal layer) having the bitcell array will be subjected to a 256 row load (capacitance and resistance) when a bitcell along the WL_msb 215a/b is activated. Similarly, each redundant array 212a/b comprises 4 bitcells and the layer (polysilicon or metal layer) having the redundant array will be subjected to a 4 bitcell load when a redundant bitcell along the rWL_msb 215a/b is activated. Thus, the charge/discharge rate of the bitcells of the bitcell arrays 210a/b may be [substantially] lower than the charge/discharge rate of the redundant bitcells 212a/b. Therefore, writing to or reading from the bitcells of the bitcell array will be slower than writing to or reading from the redundant bitcells. Put another way, writing to or reading from the redundant bitcells of the redundant array will be faster than the writing to or reading from the bitcells of the bitcell array.

As depicted in FIG. 2, the WDX circuitry 204a provides wordline (WL) signals to the bitcell arrays 210a/b. Similarly, the Rred circuitry 206 provides redundant wordline (rWL) signals to the redundant arrays 212a/b.

Furthermore, control logic 202 provides write select signals ((yw & nyw) and read select signals (yr & nyr) to the column selection circuitry 208a/208b to generate the bitline signals to select the required column of bitcells as appropriate.

In accordance with the present techniques, and as depicted in FIG. 2, the bitlines (BL & nBL) to select bitcells in a column of a bitcell array 210a/b comprise a first bitline portion (BL₁n) and a second bitline portion (BL₂n). In the illustrative example depicted in FIG. 2, the first bitline portions (BL₁n) and respective second bitline portions (BL₂n) are electrically coupled using, for example, a via at the transition region 230a/b.

Thus, when writing or reading to a particular bitcell in the bitcell array 210a, to select that particular bitcell, the column selection circuitry 208a/208b provides an appropriate signal via the bitlines (BLn/nBLn) to which that bitcell is electrically coupled, where the bitlines (BL/nBLn) each comprise a first bitline portion (BL₁n/nBL₁n) in a first layer and a second bitline portion (BL₂n/nBL₂n) in a second layer.

In accordance with the present techniques, when writing or reading to a particular redundant bitcell in the redundant array 212a, to select that particular bitcell, the column selection circuitry 208a/208b provides an appropriate signal via flexible or floating bitlines (fBLn/fnBLn) to which that bitcell is electrically coupled. In embodiments, the floating bitlines (fBL/fBLn) extend in the same layer as the bitcells [e.g. the same layer on which the gates of the bitcells are provided fabricated].

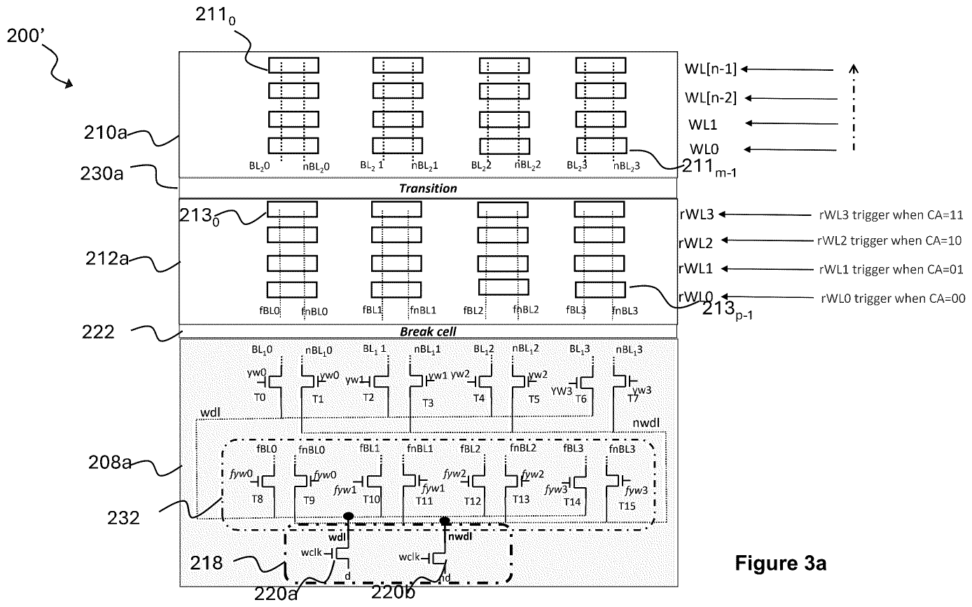

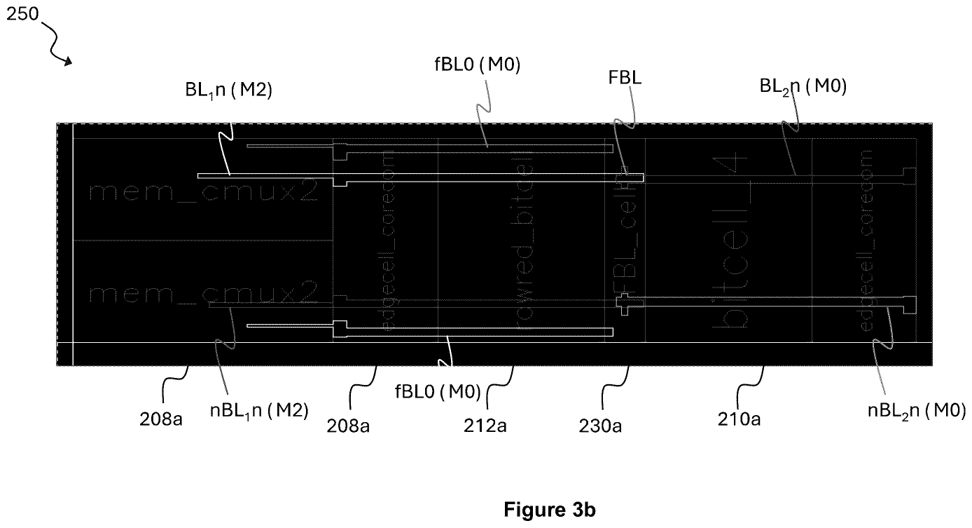

FIG. 3a shows a portion 200′ of the storage circuitry of FIG. 2 in more detail in accordance with an embodiment of the present techniques.

FIG. 3a depicts bitcell array 210a comprising “m” bitcells 211₀ to 211ₘ₋₁ (where in the present example m=1024) and associated redundant array 212a comprising “p” redundant bitcells 213₀ to 213ₚ₋₁ (where in the present example p=16).

FIG. 3a also depicts column selection circuitry 208a, which in the present example comprises CW devices designated for selecting bitcells 211m of the bitcell array 210a, where the CW devices are arranged to operate as a write multiplexer for write operations to the selected bitcells 211m.

In FIG. 3a, the CW devices are electrically coupled to the first bitline portions (BL₁n & nBL₁n), which extend along a first layer (E.g. polysilicon or metal layer) of the storage circuitry 200 along which write data will propagate. The first bitline potions BL₁n & nBL₁n are, in turn, electrically coupled to second bitline portions (BL₂n & nBL₂n) which extend along a different layer (E.g. a different polysilicon or metal layer) of the storage circuitry 200. The first bitline portions (BL₁n & nBL₁n) and second bitline portions (BL₂n & nBL₂n ) may be electrically coupled at the transition region.

In FIG. 3a, the CW devices are arranged as pass-gates comprising pairs of NMOS transistors (e.g. T0, T1, T2, T3, T4, T5, T6 & T7) that are arranged in parallel.

The transistors T0, T2, T4 & T6 are coupled to respective bitlines (BLn), where each bitline BL comprises first bitline portions (e.g. BL₁0, BL₁1, BL₁2, BL₁3) and second bitline portions (BL₂0, BL₂1, BL₂2, BL₂3) and first write data line (WDL) to receive a write data line (wdl) signal from write driver 220a of write drive circuitry 218.

The transistors T1, T3, T5 & T7 are coupled to respective bitlines (nBLn), where each bitline nBL comprises first bitline portions (e.g. nBL₁0, nBL₁1, nBL₁2, nBL₁3) and second bitline portions (nBL₂0, nBL₂1, nBL₂2, nBL₂3) and second write data line (nWDL) to receive a complementary write data line (nwdl) signal from write driver 220b of write drive circuitry 218.

The CW devices may be activated responsive to a column select signal, such as column multiplexer write select signals (yw & nyw) from the control logic (not shown in FIG. 3a).

Column multiplexer write select signals (yw & nyw) comprise transition signals provided to control the column mux write devices (CW) to, for example, couple/decouple (or connect/disconnect) a selected bitline to/from the write drive circuitry 218, where the write drive circuitry 218 comprises first write driver 220a and second write driver 220b.

In accordance with the present techniques, the column selection circuitry 208a comprises redundant column write (RCW) devices designated for selecting bitcells 213p of the redundant array 212a for write operations to the redundant bitcells 213p, where each of the RCW devices are arranged to operate as a write multiplexer for write operations to the selected redundant bitcells 213.

In FIG. 3a, the RCW devices are electrically coupled to floating bitlines (fBLn/fnBLn).

In FIG. 3a, the RCW devices are arranged as pass-gates 232 comprising pairs of NMOS transistors(e.g. T8, T9, T10, T11, T12, T13, T14 & T15) that are arranged in parallel.

The transistors T8, T10, T12 & T14 are coupled to respective floating bitlines (fBLn) (e.g. fBL0, fBL1, fBL2, fBL3) and first write data line (WDL) to receive the write data line (wdl) signal from write driver 220a of write drive circuitry 218.

The transistors T9, T11, T13 & T15 are coupled to respective floating bitlines (nfBL (e.g. nfBL0, nfBL1, nfBL2, nfBL3)) and second write data line (WDL) to receive the complementary write data line (nwdl) signal from write driver 220b write drive circuitry 218.

The RCW devices may be activated responsive to redundant column select signals, such as floating column multiplexer write select signals (fyw & fnyw) from the control logic (not shown in FIG. 3a), where redundant write select signals (fyw & nfyw) comprise transition signals to control the RCW devices to, for example, couple/decouple (or connect/disconnect) a selected floating bitline (fbl/nfbl) to/from the write drive circuitry 218.

A particular redundant bitcell in a column may be activated by selecting the bitcell's column by controlling the floating bitlines (fBL & nfBL) and triggering the redundant wordline (rWL) for the row in redundant array in which the redundant cell is located. The rWL for a particular row may be triggered responsive to a column address (CA), where, for example, rWL0 may be triggered when CA=00: rWL1 may be triggered when CA=01, rWL2 may be triggered when CA=10, rWL3 may be triggered when CA=11.

Although not shown in FIG. 3a, the column selection circuitry 208a may also include one or more CR devices designated for read operations that are arranged to operate as a read multiplexer. The CR devices are arranged as pass-gates comprising pairs of PMOS transistors arranged in parallel and coupled between the corresponding bitlines (BLn/nBLn) and sensed data lines (SDn/nSDn) which are coupled to sense amplifier (SA) circuitry.

As described above, the corresponding bitlines (BLn/nBLn) comprise first bitline portions and second bitline portions, where the first and second bitline portions are provided (fabricated) on different layers of the storage circuitry. The first and second bitline portions may be provided in electrical communication via transition region 230a

The column selection circuitry 208a may also comprise redundant column read (RCR) devices designated for selecting bitcells 213p of the redundant array 212a for read operations from the redundant bitcells 213p, where each of the RCR devices are arranged to operate as read multiplexer.

The RCR devices may be electrically coupled to floating bitlines (fBLn & fnBLn), which extend along the first layer (E.g. polysilicon or metal layer) of the storage circuitry 200.

Such a configuration in accordance with the present techniques, where the bitcell arrays and associated redundant arrays are provided on different layers, provides for the discharge rates at the at the redundant arrays to be faster than the discharge rates at the bitcell arrays, thereby mitigating any effects of a clock delay on the address set up time. Furthermore, the configuration provides for a reduction in the logic required for the address decoding.

FIG. 3b shows a block level diagram 250 of the portion 100 of the storage circuitry of FIG. 3a in more detail.

As depicted in FIG. 3b, selection circuitry 208a is electrically coupled to the first bitline portions (BL₁n & nBL₁n), which extend along a first layer (depicted as M0) of the storage circuitry along which write or read data will propagate. The first bitline potions BL₁n & nBL₁n are, in turn, electrically coupled to second bitline portions (BL₂n & nBL₂n ) which extend along a different layer (E.g. a different polysilicon or metal layer) of the storage circuitry 200. In FIG. 3b, the first bitline portions (BL₁n & nBL₁n) and second bitline portions (BL₂n & nBL₂n ) may be electrically coupled at the transition region.

In FIGS. and 3a & 3b and in the following illustrative examples the transition region 230a/b to electrically couple the respective bitline portions is described as an FBL cell 230a located between the redundant array and the bitcell array. In the present illustrative example of FIG. 3b, the transition region 230a comprises a FBL cell 230a. Depending on the technology, the FBL cell 230 may comprise, for example, a two or four contacted poly pitch (4Cpp), and an example of the transition region comprising an FBL cell is shown in FIG. 3b below. However, the claims are not limited to the transition region being in the position depicted in FIG. 3a or 3b nor are the claims limited to the transition region comprising an FBL cell, and any suitable method to electrically couple the different bitline portions.

In some embodiments, when there is an additional area constraint placed on the storage circuitry design, the column selection circuitry to select the redundant bitlines may be reduced further.

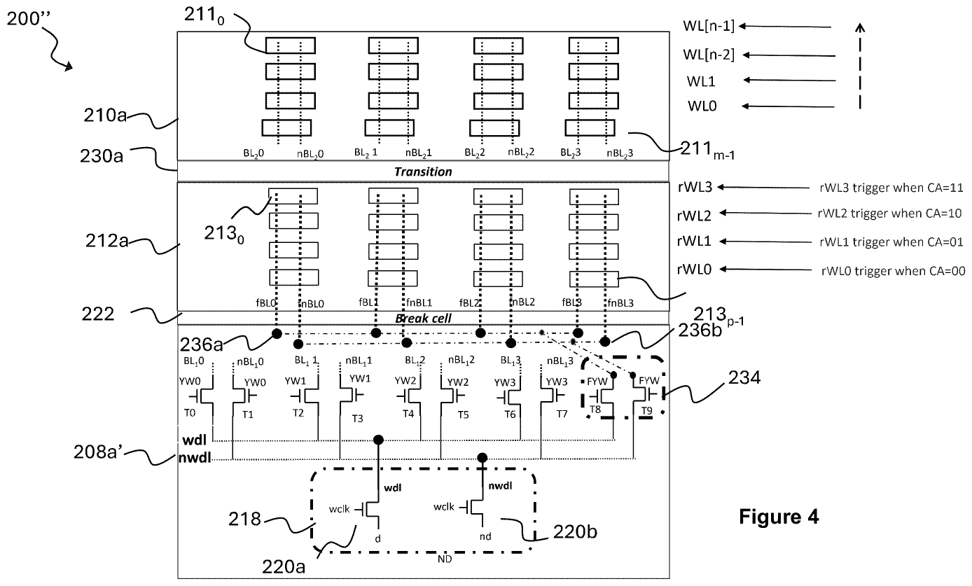

FIG. 4 shows a portion 200″ of the storage circuitry of FIG. 2 in accordance with a further embodiment of the present techniques.

FIG. 4 depicts bitcell array 210a comprising “m” bitcells 211₀ to 211ₘ₋₁ (where in the present example m=1024) and associated redundant array comprising “p” redundant bitcells 213₀ to 213ₚ₋₁ (where in the present example p=16).

FIG. 4 also depicts column selection circuitry 308a, which in the present example comprises CW devices designated for selecting bitcells 211 of the bitcell array 210a, where the CW devices are arranged to operate as a write multiplexer for write operations to the bitcells 211.

As described in FIG. 3a above, the CW devices depicted in FIG. 4 are electrically coupled to bitlines (BL & nBL), which comprise first and second bitline portions, BL₁n/nBL₁n and BL₂n/nBL₂n , where the first and second portions extend along different layers (E.g. polysilicon or metal layers) of the storage circuitry 200″. As per FIG. 3a above, the first bitline portions may be electrically coupled to second bitline portions, for example via the transition region 230a, which is depicted as an FBL cell.

As with FIG. 3a above, in FIG. 4 the RCW devices are electrically coupled to floating bitlines (fBLn & fnBLn). In an embodiment, the floating bitlines (fBLn & fnBLn) may extend along the same layer (E.g. polysilicon or metal layer) of the storage circuitry 200″ along which the write driver signals wdl/nwdl propagate to an activated bitcell.

In contrast to the embodiment of FIG. 3a, the floating bitlines (e.g. fBL0, fBL1, fBL2, fBL3) are shared in that they are all electrically coupled to one another. Similarly, complementary floating bitlines (fnBL0, fnBL1, fnBL2, fnBL3) are shared in that they are all electrically coupled to one another.

As depicted in FIG. 4, the floating bitlines(e.g. fBL0, fBL1, fBL2, fBL3) may be electrically coupled to a common electrical track (or bus) 236a/b at the column selection circuitry 208a′, although as will be appreciated the one or both of the common electrical tracks 236a and 236b may, alternatively, be provided in the bitcell array 212a.

In FIG. 4, the RCW devices are arranged as a single pass-gate 234 comprising a pair of NMOS transistors(e.g. T8, T9) that are arranged in parallel.

The output of transistor T8 is coupled between shared redundant bitlines (e.g. at a node of electrical track 236a) and first write data line (WDL) to receive a write data line (wdl) signal from first write driver 220a of the write drive circuitry 218.

Similarly, the output of transistor T9 is coupled between shared redundant bitlines (e.g. at electrical track 236b) and second write data line (nWDL) to receive an inverted write data line (nwdl) signal from second write driver 220b of the write drive circuitry 218 and to output the nwdl signal to the columns of the redundant bitcells 213 via the floating bitlines (fnBL0, fnBL1, fnBL2, fnBL3).

While all redundant bitcells will be selected responsive to the signals (wdl/nwdl) on the shared floating bitlines, a particular row of the selected redundant bitcells may be activated by triggering a redundant wordline (rWL) for that particular row. The rWL for the particular row may be triggered responsive to a column address (CA), where, for example, rWL0 may be triggered when CA=00: rWL1 may be triggered when CA=01, rWL2 may be triggered when CA=10, rWL3 may be triggered when CA=11.

Although not shown in FIG. 4, the column selection circuitry 208a′ may also include one or more CR devices designated for read operations that are arranged to operate as a read multiplexer. The CR devices are arranged as pass-gates comprising pairs of PMOS transistors arranged in parallel and coupled between the corresponding bitlines (BLn/nBLn) and sensed data lines (SDn/nSDn) which are coupled to sense amplifier (SA) circuitry.

As described above, the corresponding bitlines (BL/nBL) comprise first bitline portions and second bitline portions, where the first and second bitline portions are provided (fabricated) on different layers of the storage circuitry. The first and second bitline portions may be in electrical communication via transition region (e.g. FBL cell) 230a.

The column selection circuitry 208a′ may also comprise a redundant column read (RCR) devices designated for selecting bitcells 213p of the redundant array 212a for read operations from the redundant bitcells 213p, where the RCR device the embodiment in FIG. 4 (although not shown therein) is arranged as a single pass-gate.

A first (PMOS) transistor of the RCR device may be electrically coupled to first floating bitlines (fBL) and a second (PMOS) transistor of the RCR device may be electrically coupled to floating bitlines (fnBL). The floating bitlines (fBL & fnBL) may provided in the same layer (E.g. polysilicon or metal layer) of the storage circuitry 200 as the first bitline portions.

The embodiment depicted in FIG. 4 having the pass-gate comprising a pair of CW devices may be more suitable for storage devices that are subject to area limitations than the embodiment shown in FIG. 3a, which comprises a pass-gate having eight CW devices.

In contrast to the conventional storage circuit the present techniques provide for the bitcell array and redundant array to be provided [fabricated] at different layers of the storage circuitry.

In contrast to conventional techniques, when providing row redundancy in accordance with the present techniques, the redundant arrays are provided (e.g. fabricated) on different levels or layers (e.g. polysilicon or metal etc.) of the storage circuitry. Thus a first portion of bitlines for selecting columns of redundant bitcells in a redundant array will be on a different level as a second portion of the bitlines. The first and second bitline portions are electrically coupled at a transition region (e.g. an FBL cell) provided (fabricated) between the redundant array and bitcell array.

Although the figures above depict the redundant array and the column selection (or Cmux) circuitry 208a′ as being provided (fabricated) on the same layer (level) of the storage circuitry with the bitcell array depicted as being on a different layer, in alternative embodiments the bitcell arrays and the Cmux circuitry may be provided (fabricated) on the same layer, with the redundant arrays on a different layer.

In conventional techniques described above in FIGS. 1a and 1b, 4SC comparator logic is required to perform a comparison to determine the address of a faulty row for each redundant array.

In contrast to conventional techniques, redundant row address circuitry comprising comparator logic is provided in the Rred circuitry in accordance with the present techniques, where the comparator logic is to compare a faulty row address (fra) (i.e. the address of a known faulty row in a bitcell array, e.g. <7:0>) and a main address (add) (i.e. the address of a row in the bitcell array to be accessed, e.g. <7:0>) to generate an “nmatch” signal.

WL driver logic is to then, responsive to a match signal (i.e. the inverted match signal), generate a redundant wordline signal (rWL) indicating the address of a redundant row (e.g., <0:3>) to replace the faulty row of bitcells.

Such comparator logic comparing the fra and main address negates the requirement for the plurality of 4SC decoding and comparator logic of the conventional storage.

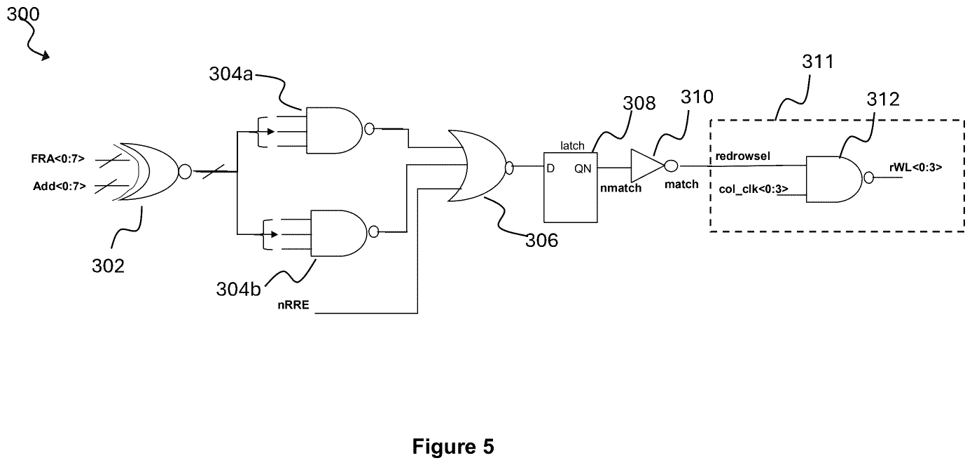

FIG. 5 shows an example logic implementation of redundant row address circuitry 300 to identify whether a main address to be accessed matches a fra, and, when there is a match, to generate a rWL indicating the address of the redundant row which is to be selected to replace the faulty row of bitcells at the fra.

In the illustrative example of FIG. 5, the circuitry 300 comprises a plurality of stages. At a first stage an XNOR logic stage receives fra and a main address as inputs, where the output from XOR is provided as inputs to NAND gates 304a/b.

The outputs from the NAND gates 304a/b are provided as inputs to NOR gate 306. The NOR gate 306 also receives a row redundancy enable (RRE) signal, which is to control the redundancy functionality. In an illustrative example, when the RRE signal is deasserted (or “low” or “0”), the redundant functionality is disabled and the circuitry does not generate a rWL even when there is a match between the main address and fra. Thus, no rWL is generated when the fra and the main address signal of a bitcell row to be accessed are different (i.e. no match) or when the RRE signal is deasserted.

When the RRE signal is asserted (or “high” or “1”), the redundant functionality is enabled and the circuitry generates a rWL signal when there is a match between the main address and fra. As depicted in FIG. 5, the NOR gate 306 receives a complementary RRE signal (nRRE).

The output from the NOR gate 306 is provided as an input (D) to latch 308.

When there is a match between the main address and fra, an output from the latch 308 (“nmatch”) is provided as an input to an inverter 310, and the output from the inverter 310 (“match”) is provided to redundant wordline (rWL) driver circuitry 311 as redundant row select signal (“redrowsel”).

The rWL driver circuitry 311 comprises NAND gate 312 and receives the “match” signal as redrowsel signal at a first input to NAND gate 312.

A clock path signal (col_clk <0:3>) is provided as a second input to the NAND gate 312, and the output from the NAND gate 312 comprises the redundant wordline address signal rwl <0:3>, which corresponds to the address of the redundant row which is to be accessed to replace the faulty row of bitcells. Thus, when the fra address and the main address signal of a bitcell row to be selected match, a match signal will be generated by the inverter logic 310 and provided to the rWL driver circuitry 311 as an input to the NAND gate 312.

The Rred circuitry may use column address decoding (CA0 and CA1) to trigger the corresponding rWL (rwl0, rwl1, rwl2 and rwl3), based on the value of CA[0:1].

For example, rWL0 may be triggered when CA=00; rWL1 may be triggered when CA=01; rWL2 may triggered when CA=10; and rWL3 may be triggered when CA=11.

Such functionality is in contrast with the conventional circuitry, where the redundant wordlines will be triggered based on matching signals through the row-address.

In the redundant row address circuitry 300 to generate the rwl address, the clock path signal (col_clk <0:3>) is delayed by one gate.

If the same comparator logic was used in the conventional storage circuitry, where the bitcell array and redundant arrays are on the same layer, there would be a timing penalty as the address setup time would be increased due to the delayed clock path signal.

However, as the bitcell arrays and redundant arrays are on different layers of the storage circuit, there is a reduced load (capacitance/resistance) on the layer having the redundant array (e.g. 4 rows of redundant bitcells) compared to the layer having the bitcell array (e.g. 256 rows of bitcells), and so the rows of redundant bitcells will be accessed faster (i.e. written to and read from) compared to the bitcells of the bitcell array.

Thus, although there is an additional delay on the clock path which may impact the address setup time for the rWL this additional delay on the clock path does not impact access time when accessing a redundant bitcell.

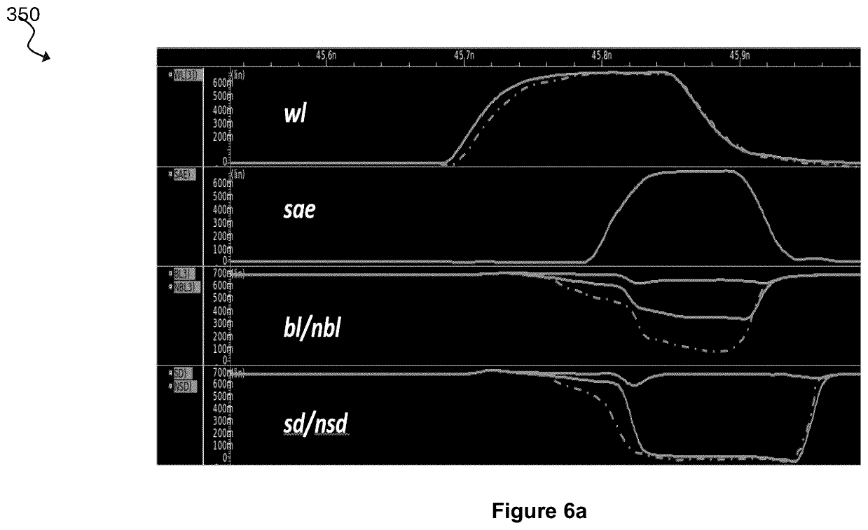

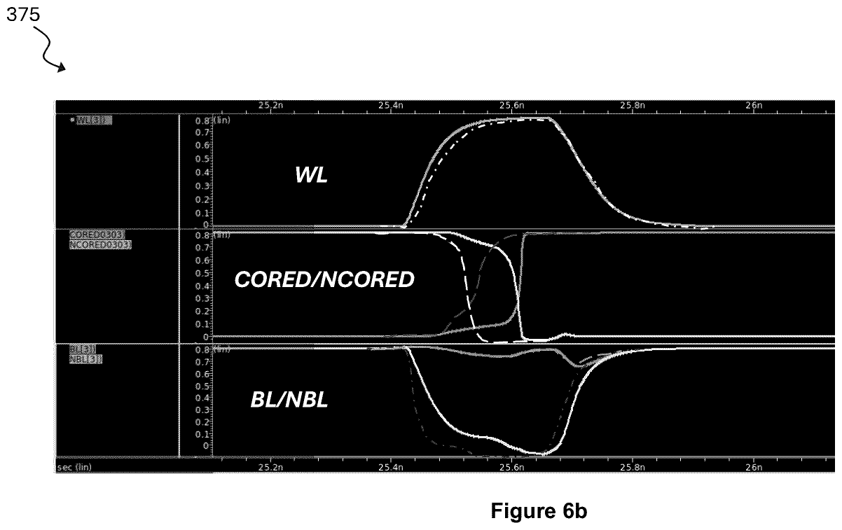

This functionality can be seen in FIGS. 6a & 6b, which show a waveform diagram 350 for a read operation (FIG. 6a) and a write operation (FIG. 6b) performed at the storage circuitry 200 in accordance with the present techniques, where the solid waveforms relate to accessing a bitcell of a bitcell array and the dashed lines relate to accessing a redundant bitcell.

As can be seen in FIGS. 6a and 6b, the wordline signal for the selected row of bitcells (depicted as a solid “wl” line in both FIGS. 6a & 6b) is delayed compared to the redundant wordline signal (depicted as a dashed “wl” line in both FIGS. 6a & 6b) for the redundant row of the redundant array. This delay results from the additional gate on the clock path when generating the redundant wordline address rwl.

The read operation is depicted by the sd/nsd signal in FIG. 6a, where the read operation for the redundant bitcell (depicted as a dashed “sd/nsd” line) is initiated sooner and completes sooner than the read operation for the bitcell of the bitcell array (depicted as a solid “sd/nsd” line).

Similarly, the write operation is depicted by the CORED/NCORED signal in FIG. 6b, where the read operation for the redundant bitcell (depicted as a dashed “CORED/NCORED” line) is initiated sooner and completes sooner than the write operation for the bitcell of the bitcell array (depicted as a solid “CORED/NCORED” line).

Thus, the additional delay on the clock path does now impact access time during a read or write operation at a redundant bitcell.

The signals from the redundant row address circuitry 300 depicted in FIG. 5 may be used to generate the column write select signals for the Cmux circuitry and/or to generate the column read select signals (yw/nyw & fyw/nfyw).

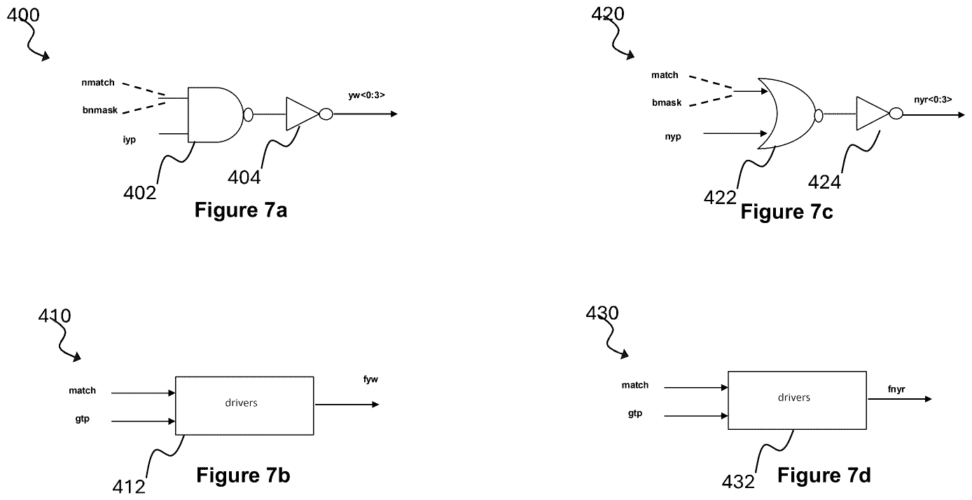

As an illustrative example, FIG. 7a shows an example of write signal generation logic 400 in accordance with the present techniques; FIG. 7b shows an example of fault write signal generation logic 410 in accordance with the present techniques; FIG. 7c shows an example of read signal generation logic 420 in accordance with the present techniques; FIG. 7d shows an example of fault read signal generation logic 430 in accordance with the present techniques.

In FIG. 7a, the write signal generation logic 400 receives the “nmatch” signal from the latch circuit shown in FIG. 5 as a first input to NAND gate 402 and receives write decode signal (iyp) as a second input to NAND gate 402. The output from NAND gate 402 is provided as an input to invertor 404 which provides the write column multiplexer write select signal yw<0:3>as an output. The write column multiplexer select signals are used to control the CW devices of the column selection circuitry depicted in FIGS. 3a and 4.

In FIG. 7b, the fault write signal generation logic 410 receives the “match” signal from the inverter shown in FIG. 5 as a first input to driver 412 and receives a global timing pulse (gtp) as a second input to driver 412, and the output from driver 412 is provided as the floating column multiplexer write select signal fyw, which is used to control the redundant CW devices of the column selection circuitry depicted in FIGS. 3a and 4.

In FIG. 7c, the read signal generation logic 420 receives the “match” signal from the latch circuit shown in FIG. 5 as a first input to NOR gate 422 and receives read decode signal (nyp) as a second input to NOR gate 422. The output from NOR gate 422 is provided as an input to invertor 424 which provides the read column multiplexer select signal nyr<0:3>as on output. The read column multiplexer select signals are used to control the CR devices of the column multiplexer selection circuitry described above.

In FIG. 7d, the fault read signal generation logic 430 receives the inverted “nmatch” signal (“match” signal) from the inverter shown in FIG. 5 as a first input to driver 430 and receives global timing pulse (gtp) as a second input to driver 430, and the output from the driver 430 is provided as the redundant column multiplexer read select signal fnyr, which is used to control the redundant CR devices of the column multiplexer selection circuitry described above.

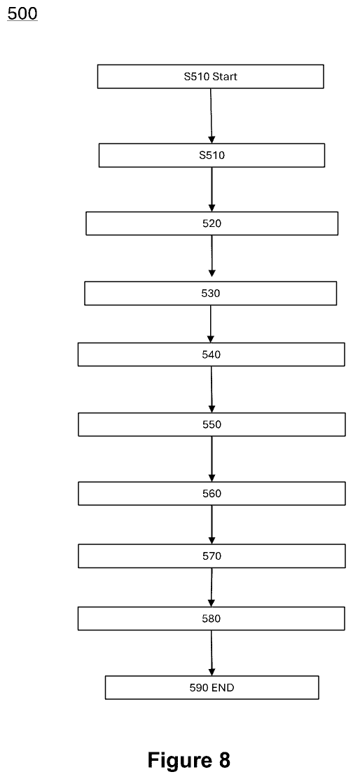

FIG. 8 illustrates a process flow diagram 500 for a manufacturing operation for fabricating an integrated circuit in accordance with various implementations described herein.

It should be understood that even though the flow diagram may indicate a particular order of operation execution, in some cases, various certain portions of the operations may be executed in a different order, and on different systems. In other cases, additional operations and/or steps may be added to and/or omitted from the operation. The manufacturing operation may be implemented in hardware and/or software. When implemented in hardware, the manufacturing operation may be implemented with various circuit components, such as described herein above in reference to FIGS. 2-7. When implemented in software, the manufacturing operation may be implemented as a program or software instruction process that may be configured for implementing storage circuitry having row redundancy as described herein. Also, when implemented in software, instructions related to implementing the manufacturing operation may be stored in memory and/or a database. For instance, a computer or various other types of computing devices having a processor and memory may be configured to perform the manufacturing operation.

As described and shown in reference to FIG. 8, manufacturing operation may be used for manufacturing (fabricating) an integrated circuit (IC) that implements row redundancy circuitry in various types of storage (e.g. memory) applications. The integrated circuit (IC) may refer to a register transfer logic (RTL) wrapper that includes memory circuitry and comparator logic that is disposed separately from the memory circuitry within the RTL wrapper.

At S510 the flow diagram starts.

At S520 the operation is to fabricate circuitry having a bitcell array comprising a plurality of bitcells arranged in rows and columns at a (first) layer (e.g. polysilicon or metal) of the storage circuitry with first bitline portions of first bitlines, the first bitline portions to select respective columns of bitcells.

At 530, the operation is to fabricate a transition region (e.g. a FBL cell) between the bitcell array and the associated redundant array.

At S540 the operation is to fabricate circuitry having a redundant array comprising a plurality of redundant bitcells arranged in rows and columns at a second layer (e.g. polysilicon or metal) with second bitlines to select respective columns of redundant bitcells.

At S550, the operation is to fabricate second bitline portions of the first bitlines at the second (or different) layer, and to provide the second bitline portions in electrical communication with the respective first bitline portions (e.g. at the transition region).

At block 560, the operation is to fabricate column selection circuitry comprising one or more column read and one or more column write devices to select the columns of bitcells via the respective first and second bitline portions and one or more redundant column read and one or more redundant column write devices to select the columns of redundant bitcells via the respective second bitlines.

At block 570, the operation is to fabricate redundant row address circuitry to compare a fra with a main address and to provide a row redundancy worldline signal to the rows of redundant bitcells when there is match.

At block 580, the operation is to fabricate wordline selection (WDX) circuitry to provide worldline signals to the rows of bitcells of the bitcell array.

At block 590, the operation ends.

The present techniques provide row redundancy circuitry to reduce area overhead in comparison to conventional storage circuitry (e.g. at system on chip SoC). The present techniques provide for mitigating the effects of any delay in row redundancy address setup time which may result from an additional gate delay in a clock path.

Various embodiments have been described within the context of SRAM, but in general embodiments are not limited to SRAM and the present techniques may be used in storage technologies other than SRAM employing row redundancy techniques.

In some instances, the storage circuitry may be implemented as an IC with dual rail memory architecture and related circuitry. In other instances, the storage circuitry may be integrated with computing circuitry and related components on a single chip.

Also, the storage circuitry may be implemented in an embedded system for various electronic and mobile applications, including low power sensor nodes or server applications.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define an HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally, or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively, or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively, or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Implementations of the present technology each have at least one of the above-mentioned objects and/or aspects, but do not necessarily have all of them. It should be understood that some aspects of the present technology that have resulted from attempting to attain the above-mentioned object may not satisfy this object and/or may satisfy other objects not specifically recited herein.

The functions of the various elements shown in the figures, including any functional elements labeled as a “block,” “module” or “processor”, may be provided through the use of dedicated hardware as well as hardware capable of executing software in association with appropriate software. When provided by a processor, the functions may be provided by a single dedicated processor, by a single shared processor, or by a plurality of individual processors, some of which may be shared. Moreover, explicit use of the term “processor” or “controller” should not be construed to refer exclusively to hardware capable of executing software, and may implicitly include, without limitation, digital signal processor (DSP) hardware, network processor, application specific integrated circuit (ASIC), field programmable gate array (FPGA), read-only memory (ROM) for storing software, random access memory (RAM), and non-volatile storage. Other hardware, conventional and/or custom, may also be included.

Software modules, or simply modules which are implied to be software, may be represented herein as any combination of flowchart elements or other elements indicating performance of process steps and/or textual description. Such modules may be executed by hardware that is expressly or implicitly shown.

Additional and/or alternative features, aspects and advantages of implementations of the present technology will become apparent from the following description, the accompanying drawings and the appended claims.

The examples and conditional language recited herein are intended to aid the reader in understanding the principles of the present technology and not to limit its scope to such specifically recited examples and conditions. It will be appreciated that those skilled in the art may devise various arrangements which, although not explicitly described or shown herein, nonetheless embody the principles of the present technology and are included within its scope as defined by the appended claims.

Furthermore, as an aid to understanding, the above description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to limit the scope or set forth the bounds of the present technology. These modifications are not an exhaustive list, and a person skilled in the art may make other modifications while nonetheless remaining within the scope of the present technology. Further, where no examples of modifications have been set forth, it should not be interpreted that no modifications are possible and/or that what is described is the sole manner of implementing that element of the present technology.

Moreover, all statements herein reciting principles, aspects, and implementations of the technology, as well as specific examples thereof, are intended to encompass both structural and functional equivalents thereof, whether they are currently known or developed in the future. Thus, for example, it will be appreciated by those skilled in the art that any block diagrams herein represent conceptual views of illustrative circuitry embodying the principles of the present technology. Similarly, it will be appreciated that any flowcharts, flow diagrams, state transition diagrams, pseudo-code, and the like represent various processes which may be substantially represented in computer-readable media and so executed by a computer or processor, whether or not such computer or processor is explicitly shown.

It will be clear to one skilled in the art that many improvements and modifications can be made to the foregoing exemplary embodiments without departing from the scope of the present techniques.

1. Storage circuitry comprising:
a bitcell array having a plurality of bitcells, each bitcell accessible via at least one bitline and at least one wordline, where the bitcell array is provided at a first layer of the storage circuitry;
a redundant array associated with the bitcell array, the redundant array having a plurality of redundant bitcells, each redundant bitcell accessed via at least one redundant bitline and at least one redundant wordline, where the bitcell array is provided at a second layer of the storage circuitry.

2. The storage circuitry of claim 1, further comprising column selection circuitry to, responsive to a column select signal, select at least one bitcell via the least one bitline, where the at least one bitline comprises a first bitline portion provided at the first layer of the storage circuitry and a second bitline portion provided at the second or third layer of the storage circuitry, and where the first bitline portion is in electrical communication with the second bitline portion.

3. The storage circuitry of claim 1, where the column selection circuitry is to, responsive to a redundant column select signal, select at least one redundant bitcell via at least one floating bitline.

4. The storage circuitry of claim 1, where the storage circuitry comprises a floating bitline cell provided between the bitcell array and the associated redundant array.

5. The storage circuitry of claim 4, where the first bitline portion is in electrical communication with the second bitline portion at a transition region.

6. The storage circuitry of claim 5, where the transition region comprises a floating bitline cell.

7. The storage circuity of claim 1, further comprising wordline selection circuitry to generate a wordline signal to select at least one bitcell.

8. The storage circuity of claim 1, further comprising redundant row wordline selection circuitry to generate a redundant wordline signal to select at least one redundant bitcell.

9. The storage circuitry of claim 8, where the redundant row wordline selection circuitry is to receive a faulty row address and a main address of at least one bitcell to be accessed in a read or write operation, and to determine whether there is a match between the faulty row address and the main address.

10. The storage circuitry of claim 9, wherein, the redundant row wordline selection circuitry is to generate a match signal responsive to a match between the faulty row address and the main address.

11. The storage circuity of claim 10, where the redundant row wordline selection circuitry is to generate the match signal responsive to a match between the faulty row address and the main address when a row redundancy enable signal is asserted.

12. The storage circuitry of claim 9, wherein the redundant row wordline selection circuitry comprises redundant wordline driver circuitry to generate the redundant wordline signal responsive to the match signal and a clock path signal.

13. The storage circuitry of claim 3, where the column selection circuitry comprises a column write device arranged between the second bitline portion and write driver circuitry to enable the write driver circuitry to store a data value at one or more accessed bitcells.

14. The storage circuitry of claim 3, where the column selection circuitry comprises one or more redundant column write device arranged between the redundant bitline and write driver circuitry to enable the write driver circuitry to store a data value at one or more accessed redundant bitcells.

15. The storage circuitry of claim 14, where a redundant column write device comprises a pass-gate to provide a word data signal to the one or more accessed bitcells.

16. The storage circuitry of claim 3, where the column selection circuitry comprises a column read device arranged between the second bitline portion and sense amplifier circuitry.

17. The storage circuitry of claim 16, where a redundant column read device comprises a pass-gate to enable the sense amplifier circuitry to sense a data value stored at one or more accessed bitcells.

18. The storage circuitry of claim 3, where the redundant bitlines are electrically coupled to a common pass-gate to select one or more columns of redundant bitcells.

19. A method of controlling a read or write operation at storage circuitry comprising a bitcell array having a plurality of bitcells, each bitcell accessible via a bitline and wordline, where the bitcell array is provided at a first layer of the storage circuitry and a redundant array associated with the bitcell array, the redundant array having a plurality of redundant bitcells, each redundant bitcell accessed via a redundant bitline and redundant wordline, where the bitcell array is provided at a second layer of the storage circuitry.

20. A non-transitory computer-readable medium to store computer-readable code for fabrication of the storage circuit of claim 1.
